(19) United States
(12) Patent Application Publication
(10) Pub. No.: US 2020/0395228 A1
(43) Pub. Date: Dec. 17, 2020

(54) SUBSTRATE TREATMENT APPARATUS

(71) Applicant: SEMES CO., LTD., Cheonan-si (KR)

(72) Inventors: Seung Hoon OH, Cheonan-si (KR); Young Jin KIM, Seoul (KR); Byung Sun BANG, Hwaseong-si (KR); Bu Young JUNG, Cheonan-si (KR); Young Hun LEE, Cheonan-si (KR); Gui Su PARK, Cheonan-si (KR)

(73) Assignee: SEMES CO., LTD., Cheonan-si (KR)

(21) Appl. No.: 16/901,686

(22) Filed: Jun. 15, 2020

(30) Foreign Application Priority Data
Jun. 17, 2019 (KR) 10-2019-0071785

(51) Int. Cl. H01L 21/67

(52) U.S. Cl. CPC H01L 21/6715

(57) ABSTRACT

A substrate treatment apparatus of The present disclosure includes: a tube connecting a storage tank in which a chemical liquid is stored and an outlet through which the chemical liquid is discharged; a venturi nozzle installed in the tube and including a chemical liquid discharge part configured to discharge to an object; and a first negative pressure control valve installed between the venturi nozzle and the outlet in the tube, wherein, when the first negative pressure control valve is opened, negative pressure is generated in the venturi nozzle to limit discharge of the chemical liquid from the chemical liquid discharge part.

### CROSS REFERENCE TO RELATED APPLICATION

The present application claims priority to Korean Patent Application No. 10-2019-0071785, filed on Jun. 17, 2019, the entire contents of which is incorporated by reference herein for all purposes.

### BACKGROUND OF THE INVENTION

### Field of the Invention

The present disclosure relates generally to a substrate treatment apparatus and, more particularly, to a substrate treatment apparatus that can be used to manufacture semiconductors.

### Description of the Related Art

Generally, as semiconductor devices have characteristics such as high density, high integration, and high-performance, circuit patterns thereof are refined, and contaminants such as particles, organic contaminants, and metal contaminants remaining on substrate surfaces effect on properties of the devices and production yield. Accordingly, a cleaning process for removing various contaminants attached to the substrate surfaces is important in the semiconductor manufacturing process, and the cleaning process for cleaning a substrate is performed at stages before and after each unit process of the semiconductor manufacturing process.

A cleaning method used in the semiconductor manufacturing process may be classified into dry cleaning and wet cleaning. The wet cleaning may be classified into a bath type in which contaminants are removed by chemical dissolving or the like by depositing a substrate in a chemical liquid, and a spin type in which contaminants are removed by supplying a chemical liquid to a surface of a substrate while the substrate placed on a spin chuck rotates.

In the spin type cleaning method, a substrate is fixed to a chuck member capable of treating a single substrate and then, while the substrate rotates, a chemical liquid or deionized water is supplied to the substrate through a spray nozzle. The substrate is cleaned while the chemical liquid or deionized water spreads to the entire surface of the substrate by a centrifugal force, and the substrate is dried with a dry gas after the cleaning process of the substrate.

The process of supplying a chemical liquid to the spray nozzle is generally controlled by opening a valve installed at a storage tank. At this point, particles may be generated as the valve is operated. Since a chemical liquid is discharged from the spray nozzle installed at a rear end of the valve, particles generated in the valve may be discharged to the substrate together with the chemical liquid.

### DOCUMENTS OF RELATED ART

(Patent Document 1) Korean Patent Application Publication No. 2014-0067892

### SUMMARY OF THE INVENTION

Accordingly, the present disclosure has been made keeping in mind the above problems occurring in the related art, and the present disclosure is intended to propose a substrate treatment apparatus capable of preventing foreign matter such as particles mixed in a chemical liquid from being discharged to a substrate.

In order to achieve the above objectives, according to one aspect of the present disclosure, there is provided a substrate treatment apparatus, the substrate treatment apparatus includes: a tube connecting a storage tank in which a chemical liquid may be stored and an outlet through which the chemical liquid may be discharged; a venturi nozzle installed in the tube and having a chemical liquid discharge part configured to discharge the chemical liquid to an object; and a first negative pressure control valve installed between the venturi nozzle and the outlet in the tube, wherein, when the first negative pressure control valve is opened, negative pressure may be generated in the venturi nozzle to limit discharge of the chemical liquid from the chemical liquid discharge part.

Further, the substrate treatment apparatus may include a bubble removing member installed in the tube and configured to remove bubbles generated in the chemical liquid.

Further, the substrate treatment apparatus may include a discharge valve coupled to the chemical liquid discharge part of the venturi nozzle and configured to control the discharge of the chemical liquid from the venturi nozzle.

Further, the substrate treatment apparatus may include a second negative pressure control valve connected to a branch tube, the branch tube being connected between the first negative pressure control valve and the venturi nozzle in the tube, and allowing negative pressure to be selectively generated in the venturi nozzle.

The storage tank and the outlet may be connected to each other so that the chemical liquid discharged from the outlet may be introduced into the storage tank and circulated.

When an initial operation of the substrate treatment apparatus is started or a process of discharging the chemical liquid to a substrate is temporarily discontinued, the first negative pressure control valve may be opened so that negative pressure may be generated in the venturi nozzle.

When foreign matter included in the chemical liquid is removed, in a state where the venturi nozzle is positioned at an area where a substrate is not positioned, the first negative pressure control valve may be closed so that the chemical liquid is discharged from the venturi nozzle.

When the chemical liquid is discharged to a substrate, in a state where the venturi nozzle is positioned at an area where the substrate is positioned, the first negative pressure control valve may be closed so that the chemical liquid may be discharged from the venturi nozzle.

Further, the substrate treatment apparatus may include a controller configured to control operations of the discharge valve, the first negative pressure control valve, and the second negative pressure control valve.

When an initial operation of the substrate treatment apparatus is started, the controller may open the first negative pressure control valve and close the discharge valve to transfer the chemical liquid stored in the storage tank to the first negative pressure control valve.

When foreign matter included in the chemical liquid is removed, the controller may close the first negative pressure control valve and open the discharge valve to discharge the chemical liquid stored in the storage tank to an area where a substrate may be not positioned for a reference time.

The reference time may be included within a range from 8 seconds to 12 seconds.

When a process of discharging the chemical liquid to a substrate is temporarily discontinued, the controller may open the first negative pressure control valve and open the discharge valve, so that negative pressure may be generated in the venturi nozzle.

When the chemical liquid is discharged to a substrate, the controller may close the first negative pressure control valve and open the discharge valve, so that the chemical liquid stored in the storage tank may be discharged to the substrate.

When a process of discharging the chemical liquid to a substrate is temporarily discontinued, the controller may close the first negative pressure control valve, open the second negative pressure control valve, and open the discharge valve, so that negative pressure may be generated in the venturi nozzle.

Unlike the conventional substrate treatment apparatus, the substrate treatment apparatus according to the present disclosure does not discharge the chemical liquid according to opening and closing of a valve installed between the storage tank and a spray nozzle. The substrate treatment apparatus of the present disclosure includes the venturi nozzle and the first negative pressure control valve. Accordingly, when the first negative pressure control valve installed in a rear end of the venturi nozzle is opened, it is possible to generate negative pressure in the venturi nozzle. That is, the substrate treatment apparatus can selectively discharge the chemical liquid by the first negative pressure control valve.

The chemical liquid flows from the venturi nozzle toward the first negative pressure control valve. Accordingly, even when particles are generated during the process of operating the first negative pressure control valve, it is possible to prevent the particles from being discharged through the venturi nozzle to the substrate.

Further, the substrate treatment apparatus of the present disclosure includes the controller, the first negative pressure control valve, and the discharge valve. Accordingly, the controller can control whether the chemical liquid is discharged by causing negative pressure to be generated in the venturi nozzle while controlling the first negative pressure control valve and the discharge valve.

As described above, unlike the conventional substrate treatment apparatus that controls the valve installed in a rear end of the storage tank, the substrate treatment apparatus of the present disclosure can discharge the chemical liquid by controlling the first negative pressure control valve installed in the rear end of the venturi nozzle and the discharge valve. Accordingly, the substrate treatment apparatus of the present disclosure is configured such that the chemical liquid discharged from the venturi nozzle does not include foreign matter, so that the substrate treatment apparatus can prevent the foreign matter from being discharged to the substrate.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view showing a substrate treatment apparatus according to a first embodiment of the present disclosure;

FIG. 2 is a view showing an inside of a venturi nozzle;

FIG. 3 is a flowchart showing a substrate treatment method for treating a substrate using the substrate treatment apparatus of FIG. 2;

FIG. 4 is a view showing a substrate treatment apparatus according to a second embodiment of the present disclosure;

FIG. 5 is a view showing a substrate treatment apparatus according to a third embodiment of the present disclosure;

FIG. 6 is a view showing a substrate treatment apparatus according to a fourth embodiment of the present disclosure;

FIGS. 7 to 10 are views showing operation processes in various situations of the substrate treatment apparatus according to the fourth embodiment of the present disclosure;

FIG. 7 is a view showing a situation in which a controller controls each valve in a process preparation stage;

FIG. 8 is a view showing a situation in which the controller controls each valve in a foreign matter removing stage;

FIG. 9 is a view showing a situation in which the controller controls each valve in a venturi nozzle moving stage and a venturi nozzle return stage;

FIG. 10 is a view showing a situation in which the controller controls each valve in a chemical liquid discharge stage;

FIG. 11 is a view showing a substrate treatment apparatus according to a fifth embodiment of the present disclosure; and

FIG. 12 is a view showing an operation process of the substrate treatment apparatus of FIG. 1, wherein the controller controls each valve in the venturi nozzle moving stage and the venturi nozzle return stage.

### DETAILED DESCRIPTION OF THE INVENTION

Hereinbelow, exemplary embodiments of the present invention will be described in detail with reference to the accompanying drawings such that the invention can be easily embodied by one of ordinarily skill in the art to which the invention belongs. Various changes to the embodiments of the invention are possible, and the scope of the invention is not limited to the embodiments described below.

In order to clearly describe the present invention, elements incorporated herein will be omitted when it may make the subject matter of the present invention unclear, and the same reference numerals will be used throughout the specification to refer to the same or like elements or parts.

In addition, in various embodiments, elements having the same configuration will be described with the same reference numerals in only the exemplary embodiment, and in other embodiments, only elements different from the exemplary embodiment will be described.

In the specification, it will be understood that when an element is referred to as being “connected” to another element, it can be “directly connected” to the other element or “indirectly connected” to the other element with intervening elements in between. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present invention belongs. It will be further understood that terms used herein should be interpreted as having a meaning that is consistent with their meaning in the context of this specification and the relevant art and will not be interpreted in an idealized or overly formal sense unless expressly so defined herein.

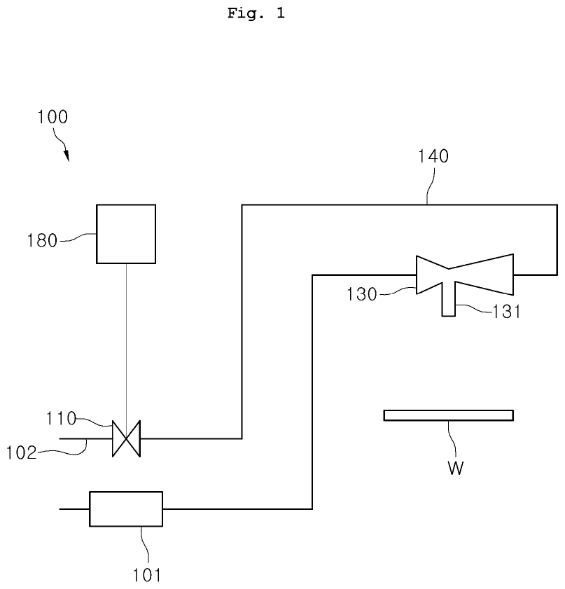

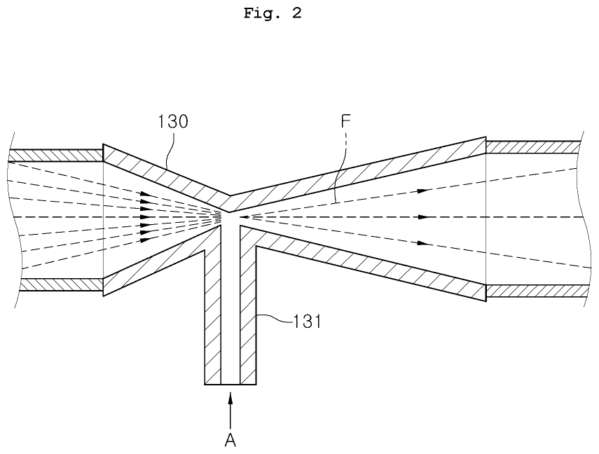

Referring to FIGS. 1 and 2, a substrate treatment apparatus 100 according to a first embodiment of the present disclosure includes a tube 140, a venturi nozzle 130, and a first negative pressure control valve 110.

The tube 140 may connect a storage tank 101 in which a chemical liquid F is stored and an outlet 102 through which the chemical liquid F is discharged. Here, the chemical liquid F may be stored in the storage tank 101. The chemical liquid F may be pumped by a pump (not shown) to be supplied to the tube 140. The storage tank 101 and the pump (not shown) may be included in a general substrate treatment apparatus, and detailed descriptions thereof will be omitted.

Meanwhile, the chemical liquid F may be used for a variety of purposes. The chemical liquid F may be at least one selected from a group consisting of hydrofluoric acid (HF), sulfuric acid (H3SO4), nitric acid (HNO3), phosphoric acid (H3PO4), SC-1 liquid (mixed liquid of ammonium hydroxide (NH4OH), hydrogen peroxide (H₂O2), and water (H2O)), deionized water (DIW), iso propyl alcohol (IPA).

The outlet 102 discharges the chemical liquid F. The discharged chemical liquid F may be recovered in a chemical recovery part (not shown) and be reused, or may be separately stored depending on the type of chemical liquid F, but is not limited thereto.

The venturi nozzle 130 is installed in the tube 140. The venturi nozzle 130 may include a body section and a chemical liquid discharge part 131. The chemical liquid discharge part 131 may be connected to the body section and discharge the chemical liquid F to an object.

As shown in FIG. 2, an interior of the venturi nozzle 130 may be formed in a venturi shape. For example, the body section of the venturi nozzle 130 may have the interior of the venturi shape. According to Bernoulli's principle, the venturi shape may have the lowest pressure in an area of a central portion, which has the smallest pipe area, than opposite ends with large pipe areas. The fluid passing along the same flow line has a lower pressure when the fluid velocity is increased.

When the chemical liquid discharge part 131 is connected to a portion where the velocity of fluid W is increased, and when the chemical liquid F passes through the venturi nozzle 130 while the first negative pressure control valve 110 described later is opened, the pressure of the chemical liquid discharge part 131 may be lower than pressure of surrounding thereof. Meanwhile, the substrate treatment apparatus 100 according to the first embodiment of the present disclosure may include a chamber (not shown). Since the venturi nozzle 130 may be positioned inside the chamber, air A inside the chamber may be introduced into the chemical liquid discharge part 131 having relatively low pressure. Therefore, since the air A is mixed with the chemical liquid F passing through the venturi nozzle 130 and then is transferred to the first negative pressure control valve 110, the chemical liquid F is not discharged through the chemical liquid discharge part 131.

The first negative pressure control valve 110 may be installed between the venturi nozzle 130 and the outlet 102 in the tube 140. When the first negative pressure control valve 110 is opened, negative pressure is generated in the venturi nozzle 130. Further, it may be limited that the air A is introduced from the outside of the venturi nozzle 130 into the tube 140 and the chemical liquid F is discharged from the chemical liquid discharge part 131.

On the other hand, when the first negative pressure control valve 110 is closed, negative pressure may be removed from the venturi nozzle 130. Accordingly, the chemical liquid F may be discharged through the venturi nozzle 130 to the outside. That is, when the substrate treatment apparatus 100 starts operation, while the chemical liquid F is continuously transferred along the tube 140, the discharge of the chemical liquid F may be controlled according to whether the first negative pressure control valve 110 is opened. The discharged chemical liquid F may etch or peel contaminants on a substrate W.

As described above, unlike the conventional substrate treatment apparatus, the substrate treatment apparatus 100 according to the first embodiment of the present disclosure does not discharge the chemical liquid according to opening and closing of a valve which is installed between the storage tank and a spray nozzle. As the substrate treatment apparatus 100 according to the first embodiment of the present disclosure includes the venturi nozzle 130 and the first negative pressure control valve 110, when the first negative pressure control valve 110 installed at a rear end of the venturi nozzle 130 is opened, negative pressure may be generated in the venturi nozzle 130. That is, the substrate treatment apparatus 100 controls the first negative pressure control valve 110 to selectively discharge the chemical liquid F.

The chemical liquid F flows from the venturi nozzle 130 toward the first negative pressure control valve 110. Therefore, even when particles are generated during the process of operating the first negative pressure control valve 110, it is possible to prevent particles from being discharged through the venturi nozzle 130 to the substrate W.

Before describing an operation process of the substrate treatment apparatus 100 according to the first embodiment of the present disclosure described above, an operation process of the general substrate treatment apparatus will be briefly described.

When the substrate is seated on a rotational plate (not shown), the chemical liquid is discharged to the substrate and treatment of a substrate surface may be performed. When the substrate is not seated on the rotational plate, the venturi nozzle may be positioned at a waiting port (not shown) away from the rotational plate.

Next, when the substrate is seated on the rotational plate, the venturi nozzle may be moved from the waiting port and be positioned above the rotational plate. Thereafter, the venturi nozzle may discharge the chemical liquid to the substrate and then return to the waiting port.

Hereinbelow, a substrate treatment method S100 using the substrate treatment apparatus 100 according to the first embodiment of the present disclosure will be described with reference to the drawings.

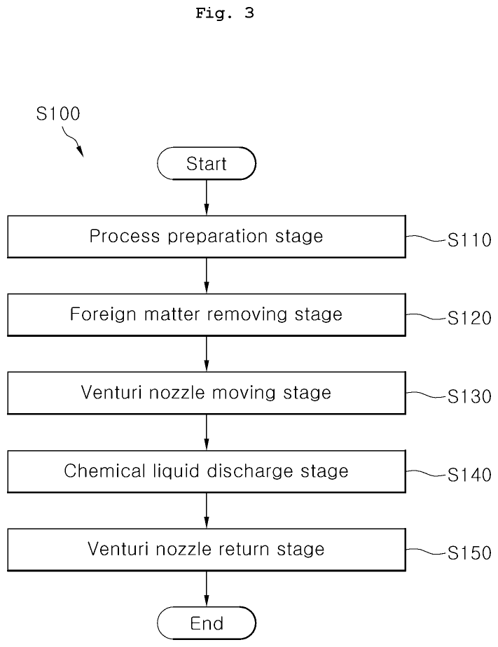

Referring to FIG. 3, the substrate treatment method S100 may include a process preparation stage S110, a venturi nozzle moving stage S130, a chemical liquid discharge stage S140, and a venturi nozzle return stage S150.

In the process preparation stage S110, a substrate treatment process is prepared and the substrate may not be seated on the rotational plate. The process preparation stage S110 may be an initial driving state for preparing the substrate treatment process.

In the process preparation stage S110, the first negative pressure control valve 110 may be opened. Therefore, negative pressure is generated in the venturi nozzle 130, and the chemical liquid stored in the storage tank 101 may pass through the venturi nozzle 130 and be transferred to the first negative pressure control valve 110.

The venturi nozzle moving stage S130 is for treating the substrate, and in this stage, the venturi nozzle 130 may be moved from the waiting port to the rotational plate where the substrate is seated. The first negative pressure control valve 110 may be opened in the venturi nozzle moving stage S130. Therefore, negative pressure may be generated in the venturi nozzle 130, and the chemical liquid may not be discharged from the venturi nozzle 130.

In the chemical liquid discharge stage S140, the chemical liquid may be discharged from the venturi nozzle 130 toward the substrate. In the chemical liquid discharge stage S140, when the venturi nozzle 130 is positioned at an area where the substrate is positioned, as the first negative pressure control valve 110 is closed, negative pressure may be removed in the venturi nozzle 130 and the chemical liquid transferred along the tube 140 may be discharged to the substrate W. Here, it may be preferable that the venturi nozzle 130 is positioned above the substrate W.

In the venturi nozzle return stage S150, the substrate treatment may be completed by the chemical liquid and the venturi nozzle 130 may be moved from the rotational plate to the waiting port. In the venturi nozzle return stage S150, the first negative pressure control valve 110 may be opened as in the venturi nozzle moving stage S130. Therefore, negative pressure may be generated in the venturi nozzle 130 and the chemical liquid may not be discharged from the venturi nozzle 130.

Meanwhile, the substrate treatment method S100 may include a foreign matter removing stage S120.

In the foreign matter removing stage S120, foreign matter that may remain inside the tube 140 may be removed. The foreign matter removing stage S120 may be performed when the substrate treatment process is started and the substrate is introduced into the chamber and is seated on the rotational plate. The foreign matter removing stage S120 may be performed immediately after the process preparation stage S110.

In the foreign matter removing stage S120, the first negative pressure control valve 110 may be closed for a predetermined time. Accordingly, the chemical liquid may be discharged through the chemical liquid discharge part 131. While the venturi nozzle 130 is moved to an area where the substrate is not positioned, the foreign matter removing stage S120 may be performed.

For example, when the venturi nozzle 130 is positioned in the waiting port, the chemical liquid may be discharged for a predetermined time. Accordingly, foreign matter such as particles remaining in the tube 140 may be removed in advance. However, it is not limited that the foreign matter removing stage S120 is performed when the venturi nozzle 130 is positioned in the waiting port, and the foreign matter removing stage S120 may be performed as long as the venturi nozzle 130 is positioned in the area where the substrate is not positioned.

Meanwhile, the first negative pressure control valve 110 may be controlled by a controller 180, which will be described later.

Back to FIG. 1, as described above, the substrate treatment apparatus 100 according to the first embodiment of the present disclosure may control the discharge of the chemical liquid by the negative pressure that is generated in the venturi nozzle 130 by the operation of the first negative pressure control valve 110. Accordingly, compared to the conventional substrate treatment apparatus controlling the valve installed at a front end of the nozzle, the substrate treatment apparatus 100 according to the first embodiment of the present disclosure may be configured such that the chemical liquid discharged from the venturi nozzle does not include foreign matter, so that it is possible to prevent foreign matter from being discharged to the substrate.

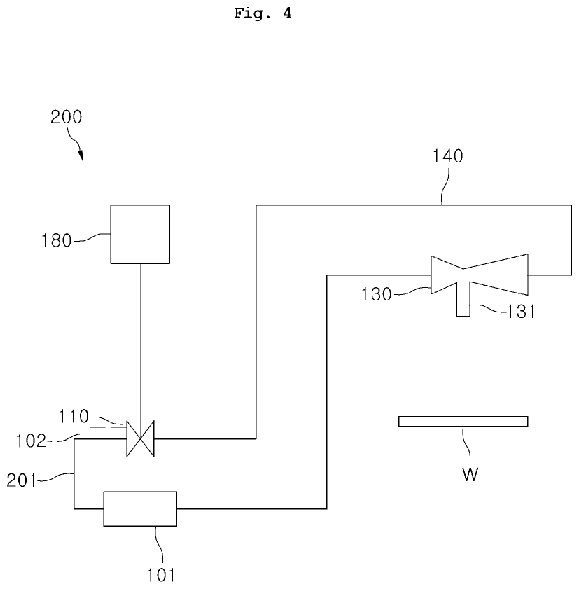

Referring to FIG. 4, a substrate treatment apparatus 200 according to a second embodiment of the present disclosure may be configured such that the storage tank 101 and the outlet 102 are connected to each other. Therefore, the substrate treatment apparatus 200 may include a circulation tube 201 and the circulation tube 201 may connect the storage tank 101 and the outlet 102.

Accordingly, the chemical liquid discharged from the outlet 102 may be introduced into the storage tank 101. That is, when negative pressure is generated in the venturi nozzle 130, the chemical liquid in the storage tank 101 passing through the venturi nozzle 130 and the outlet 102 is re-introduced into the storage tank 101 through the circulation tube 201, so that the chemical liquid may continue to be circulated. The substrate treatment apparatus 200 according to the second embodiment of the present disclosure may be reused by circulating the chemical liquid, so that the amount of chemical liquid used to treat the substrate W may be reduced. Accordingly, the substrate treatment apparatus 200 according to the second embodiment of the present disclosure can lower substrate treatment costs.

Meanwhile, although not shown in the drawings, it is possible that the circulation tube 201 is provided with a foreign matter removing part (not shown). The foreign matter removing part may remove foreign matter included in the chemical liquid.

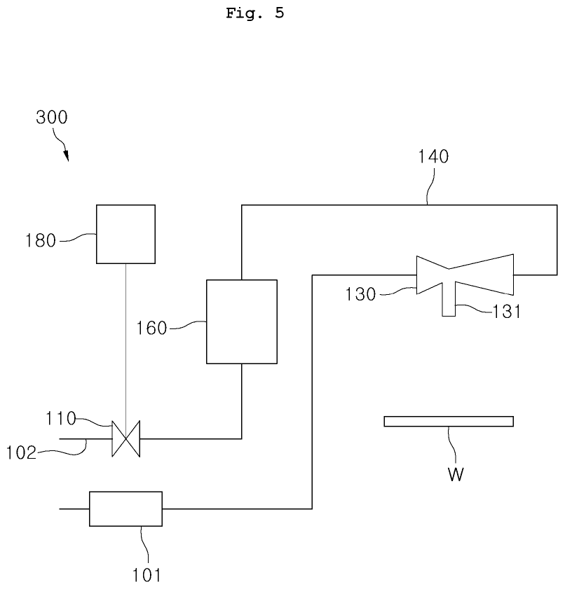

Referring to FIG. 5, a substrate treatment apparatus 300 according to a third embodiment of the present disclosure may include a bubble removing member 160.

The bubble removing member 160 may be installed in the tube 140 and remove bubbles generated in the chemical liquid. The bubble removing member 160 may be installed at a front end of the first negative pressure control valve 110 in the tube 140. For example, the bubble removing member 160 may be installed between the first negative pressure control valve 110 and the venturi nozzle 130 in the tube 140.

When the negative pressure is generated in the venturi nozzle 130, air may be introduced into the inside through the chemical liquid discharge part 131 and bubbles may be generated in the chemical liquid passing through the venturi nozzle 130. The bubble removing member 160 may remove the bubbles included in the chemical liquid. Accordingly, it is possible to prevent the chemical liquid including the bubbles from being introduced into the storage tank 101, and consequently, to prevent the chemical liquid including the bubbles from being discharged from the venturi nozzle 130.

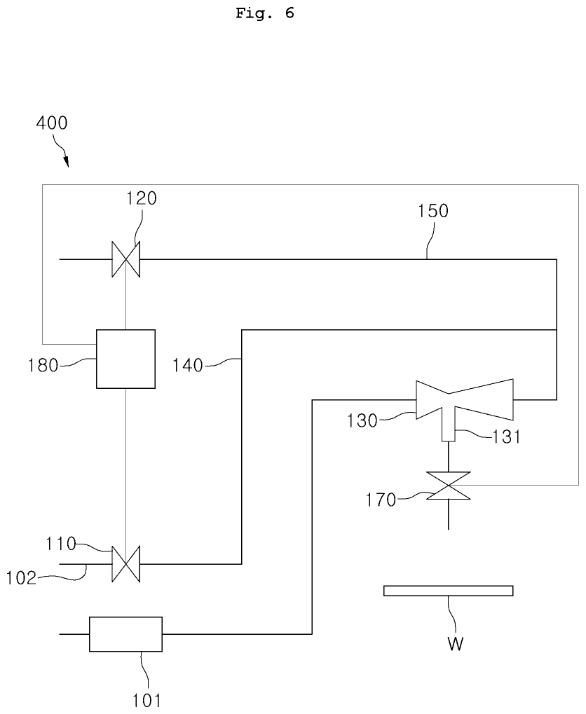

Referring to FIG. 6, a substrate treatment apparatus 400 according to a fourth embodiment of the present disclosure may include a discharge valve 170.

The discharge valve 170 may be coupled to the chemical liquid discharge part 131 of the venturi nozzle 130. The discharge valve 170 may control the discharge of the chemical liquid from the venturi nozzle 130. When the discharge valve 170 is closed, inflow of air through the chemical liquid discharge part 131 is blocked, thereby minimizing the possibility of bubbles generated in the chemical liquid flowing through the venturi nozzle 130 without the bubble removing member 160. Further, the discharge valve 170 may prevent the chemical liquid from being incorrectly discharged as negative pressure is not normally generated in the venturi nozzle 130.

When the substrate treatment apparatus 400 according to the fourth embodiment of the present disclosure starts operation, the discharge valve 170 may be maintained in a closed state for a predetermined time so that the chemical liquid may be circulated, and may always be maintained in an opened state in the process of treating the substrate W. Further, the substrate treatment apparatus 400 according to the fourth embodiment of the present disclosure may include a second negative pressure control valve 120.

The second negative pressure control valve 120 may be installed in a branch tube 150, the branch tube 150 being connected between the first negative pressure control valve 110 and the venturi nozzle 130 in the tube 140. The second negative pressure control valve 120 may allow negative pressure to be selectively generated in the venturi nozzle 130.

As the second negative pressure control valve 120 and the above-described first negative pressure control valve 110 are selectively opened and closed, negative pressure may be generated in the venturi nozzle 130.

Meanwhile, the substrate treatment apparatus 400 according to the fourth embodiment of the present disclosure may include the controller 180. The controller 180 may control operations of the discharge valve 170, the first negative pressure control valve 110, and the second negative pressure control valve 120.

Hereinbelow, an overall operation process of the substrate treatment apparatus 400 by the controller in each stage of the substrate treatment method (S100, referring to FIG. 3) described above will be described in detail with reference to the drawings. The substrate treatment apparatus 400 according to the fourth embodiment of the present disclosure may have the same basic operation stages as the substrate treatment apparatus (100, referring to FIG. 1) according to the first embodiment of the present disclosure, and a description of the operation of the discharge valve 170 added in comparison with the substrate treatment apparatus (100, referring to FIG. 1) according to the first embodiment of the present disclosure may be added.

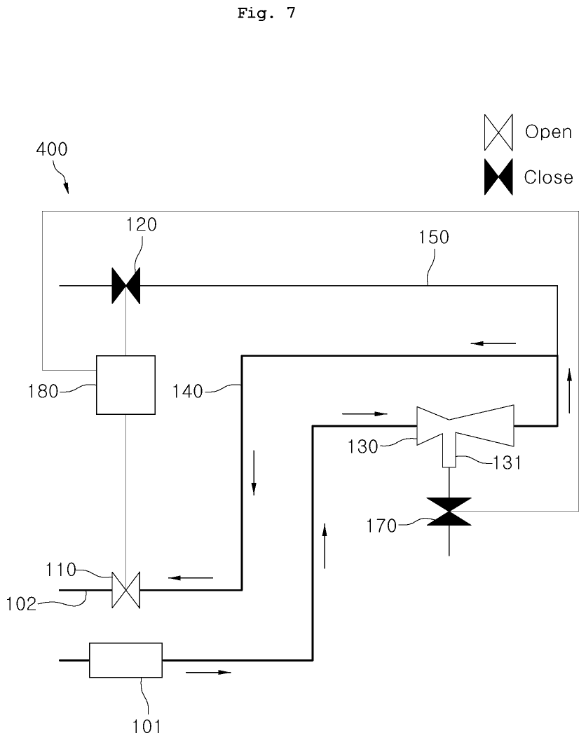

FIGS. 7 to 10 are views for showing operation processes in various situations of the substrate treatment apparatus according to the fourth embodiment of the present disclosure.

<Process Preparation Stage>

Referring to FIG. 7, the process preparation stage may be a state in which an initial operation of the substrate treatment apparatus is started and the substrate treatment apparatus 400 is before starting the substrate treatment process, that is, the substrate is not introduced into the chamber. In this state, the substrate treatment apparatus 400 may circulate the chemical liquid F without discharging the chemical liquid through the chemical liquid discharge part 131 of the venturi nozzle 130.

In this state, the controller 180 may open the first negative pressure control valve 110 and close the discharge valve 170. Here, the second negative pressure control valve 120 may be closed. Therefore, the chemical liquid stored in the storage tank 101 may circulate while passing through the venturi nozzle 130 and then being transferred to the first negative pressure control valve 110. Here, since the discharge valve 170 is closed, air is not introduced into the chemical liquid circulated along the tube 140, thereby minimizing the possibility of bubbles generated in the circulated chemical liquid.

<Foreign Matter Removing Stage>

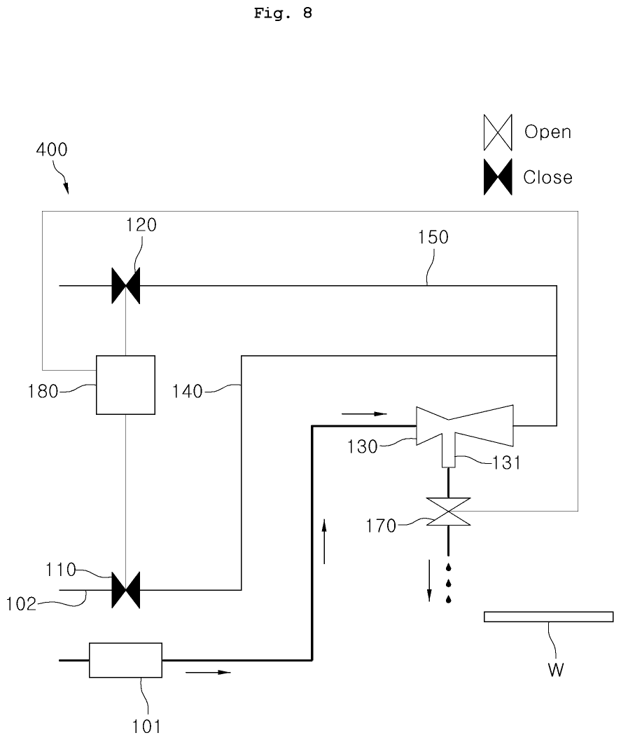

Referring to FIG. 8, the foreign matter removing stage may be a state in which the discharge valve 170 is opened before the venturi nozzle 130 is moved to an upper portion of the substrate, that is, the substrate treatment process is started and the substrate is introduced into the chamber to be seated on the rotational plate (not shown). In this state, the controller 180 may close the first negative pressure control valve 110 and open the discharge valve 170 so that the chemical liquid may be discharged through the chemical liquid discharge part 131. Here, the second negative pressure control valve 120 may be closed.

The controller 180 may allow the chemical liquid to be discharged to the area where the substrate W is not positioned for a reference time. For example, when the venturi nozzle 130 is positioned at the waiting port, the chemical liquid may be discharged for the predetermined time. Accordingly, foreign matter such as particles generated by the operation of the discharge valve 170 may be removed in advance.

Meanwhile, the reference time may be included within a range from 8 seconds to 12 seconds. When the reference time is less than 8 seconds, it may be difficult to sufficiently remove foreign matter. On the other hand, when the reference time exceeds 12 seconds, the chemical liquid may be excessively discharged and process time may be increased by chemical liquid discharge time, so that substrate productivity may be reduced.

<Venturi Nozzle Moving Stage and Venturi Nozzle Return Stage>

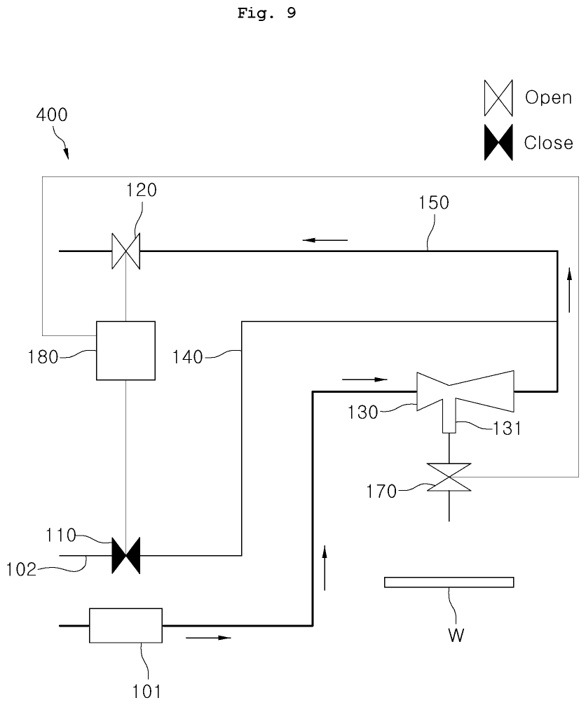

Referring to FIG. 9, in the venturi nozzle moving stage and the venturi nozzle return stage, the process of discharging the chemical liquid to the substrate W is temporarily discontinued and the controller 180 may be operated in the same manner in the two stages. The controller 180 may close the first negative pressure control valve 110, open the second negative pressure control valve 120, and open the discharge valve 170. Accordingly, the controller 180 may allow negative pressure to be generated in the venturi nozzle 130. Therefore, the chemical liquid may not be discharged from the venturi nozzle 130.

Meanwhile, the operation of the controller in the venturi nozzle moving stage and the venturi nozzle return stage is a process of temporarily discontinuing the discharge of the chemical liquid. Further, in addition to the venturi nozzle moving situation, when the process of discharging chemical liquid to the substrate W is unexpectedly discontinued in the substrate treatment process, the operation of the controller may be performed in the same manner as the situation in which the venturi nozzle is moved.

<Chemical Liquid Discharge Stage>

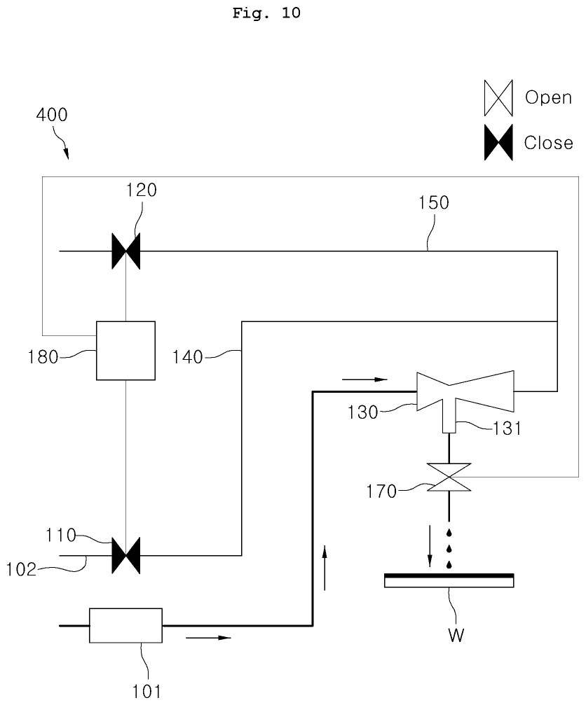

Referring to FIG. 10, in the chemical liquid discharge stage, the controller 180 may close the first negative pressure control valve 110 and open the discharge valve 170. In this stage, the second negative pressure control valve 120 may be closed. Accordingly, the controller 180 may allow chemical liquid stored in the storage tank 101 to be discharged to the substrate W.

As described above, except for closing the discharge valve 170 (referring to FIG. 7) for circulating the chemical liquid in the tube 140 before the substrate treatment process, the controller 180 may always open the discharge valve 170 in all other situations. In other words, since the discharge valve 170 may be maintained in a continuously opened state during the operation process of the substrate treatment apparatus 400, it is possible to prevent foreign matter such as particles from being generated while the discharge valve 170 is operated.

In the process preparation stage, the foreign matter removing stage, and the chemical liquid discharge stage, the controller 180 may close the second negative pressure control valve 120. On the other hand, the controller 180 may open the second negative pressure control valve 120 in the venturi nozzle moving stage and the venturi nozzle return stage.

As the venturi nozzle moving stage and the venturi nozzle return stage are performed, air introduced from the discharge valve 170 may be discharged through the second negative pressure control valve 120. That is, the second negative pressure control valve 120 may perform a bubble removing function similar to the bubble removing member (160, referring to FIG. 5) described above.

As described above, the substrate treatment apparatus 400 of the present disclosure may include the controller 180, the first negative pressure control valve 110, and the discharge valve 170. Further, it is possible to control whether chemical liquid is discharged by the controller 180 allowing negative pressure to be selectively generated in the venturi nozzle 130 while controlling the first negative pressure control valve 110 and the discharge valve 170.

As described above, unlike the conventional substrate treatment apparatus controlling the valve installed in a rear end of the storage tank 101, the substrate treatment apparatus 400 of the present disclosure may control the first negative pressure control valve 110 installed in the rear end of the venturi nozzle 130 and the discharge valve 170 to adjust the discharge of the chemical liquid. Accordingly, the substrate treatment apparatus 400 of the present disclosure may be configured such that foreign matter may not be included in the chemical liquid discharged from the venturi nozzle 130, so that it is possible to prevent foreign matter from being discharged to the substrate W.

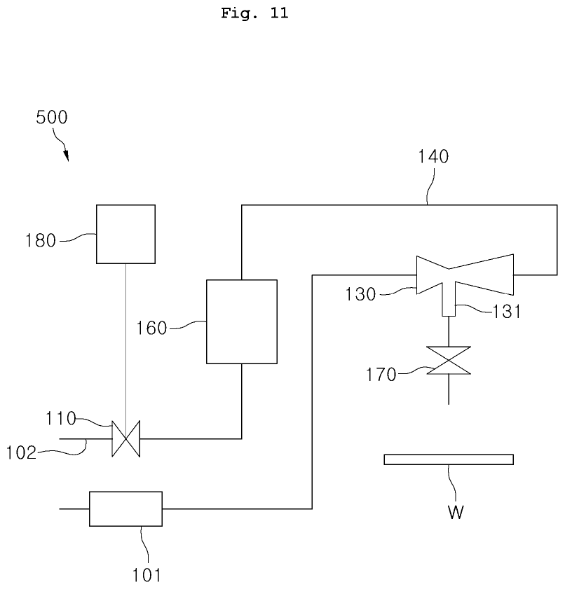

Referring to FIG. 11, a substrate treatment apparatus 500 according to a fifth embodiment of the present disclosure may include the discharge valve 170 without the second negative pressure control valve 120.

In the venturi nozzle moving stage and the venturi nozzle return stage, in the case in that air introduced through the chemical liquid discharge part 131 does not cause any major problems in the process or the bubble removing member 160 is installed in the tube 140, the substrate treatment apparatus 500 according to the fifth embodiment of the present disclosure may be operated with the discharge valve 170 without the second negative pressure control valve 120. Hereinbelow, an operation process of the substrate treatment apparatus 500 according to the fifth embodiment of the present disclosure will be described with reference to the drawings.

In the operation process of the substrate treatment apparatus (400, referring to FIG. 6) according to the fourth embodiment, the second negative pressure control valve 120 always remains to be closed in the process preparation stage, the foreign matter removing stage, and the chemical liquid discharge stage. Accordingly, even when the second negative pressure control valve 120 is not provided in the substrate treatment apparatus, there is practically no problem in the operation of the substrate treatment apparatus. Therefore, the operation process of the substrate treatment apparatus 500 according to the fifth embodiment of the present disclosure in the above three stages will be omitted.

On the other hand, in the operation process of the substrate treatment apparatus (400, referring to FIG. 6) according to fourth embodiment, when the process of discharging the chemical liquid to the substrate is temporarily discontinued, the second negative pressure control valve 120 is opened. Therefore, the operation process of the substrate treatment apparatus 500 according to the fifth embodiment when the process of discharging chemical liquid to the substrate is temporarily discontinued will be described.

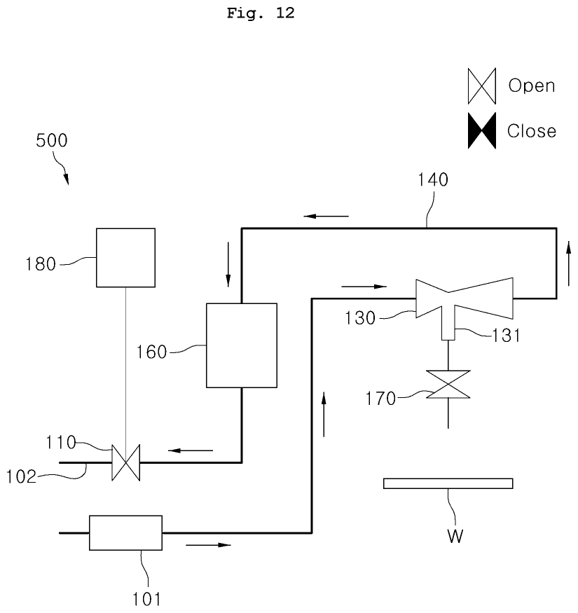

Referring to FIG. 12, when the process of discharging chemical liquid to the substrate is temporarily discontinued, the controller 180 included in the substrate treatment apparatus 500 according to the fifth embodiment of the present disclosure may open the first negative pressure control valve 110 and open the discharge valve 170. Accordingly, the controller 180 may allow negative pressure to be generated in the venturi nozzle 130. Therefore, the chemical liquid may not be discharged from the venturi nozzle 130.

Since the substrate treatment apparatus 500 according to the fifth embodiment of the present disclosure has the bubble removing member 160 in comparison to the substrate treatment apparatus (400, referring to FIG. 6) described above, it is possible to minimize the possibility of bubbles generated in the chemical liquid, and to prevent the chemical liquid from being incorrectly discharged to the substrate. Further, the substrate treatment apparatus 500 according to the fifth embodiment of the present disclosure is configured without the second negative pressure control valve 120, so that the overall structure thereof may be relatively simplified.

Although embodiments of the present disclosure has been described for illustrative purposes, they are used only for the purpose of describing the present disclosure and are not intended to limit meaning or the scope of the present disclosure as defined in the claims. Therefore, those skilled in the art will appreciate that various modifications, additions and substitutions are possible. The scope of the protection of the present disclosure should be defined by the spirit of the claims and equivalents thereof.

What is claimed is:

1. A substrate treatment apparatus comprising:
a tube connected to a storage tank in which a chemical liquid is stored;
an outlet through which the chemical liquid is discharged;
a venturi nozzle installed in the tube and having a chemical liquid discharge part configured to discharge the chemical liquid to an object; and
a first negative pressure control valve installed between the venturi nozzle and the outlet in the tube, wherein, when the first negative pressure control valve is opened, negative pressure is generated in the venturi nozzle to limit discharge of the chemical liquid from the chemical liquid discharge part.

2. The substrate treatment apparatus of claim 1, further comprising:
a bubble removing member installed in the tube and configured to remove bubbles generated in the chemical liquid.

3. The substrate treatment apparatus of claim 1, further comprising:
a discharge valve coupled to the chemical liquid discharge part of the venturi nozzle and configured to control the discharge of the chemical liquid from the venturi nozzle.

4. The substrate treatment apparatus of claim 3, further comprising:
a second negative pressure control valve connected to a branch tube, the branch tube being connected between the first negative pressure control valve and the venturi nozzle in the tube, and allowing the negative pressure to be selectively generated in the venturi nozzle.

5. The substrate treatment apparatus of claim 4,
wherein the storage tank and the outlet are connected by a circulation tube so that the chemical liquid discharged from the outlet is introduced into the storage tank and circulated.

6. The substrate treatment apparatus of claim 1, further comprising:
a controller, when an initial operation of the substrate treatment apparatus is started or a process of discharging the chemical liquid to a substrate is temporarily discontinued, configured to cause the first negative pressure control valve to open so that negative pressure is generated in the venturi nozzle.

7. The substrate treatment apparatus of claim 1, wherein when foreign matter included in the chemical liquid is removed, in a state where the venturi nozzle is positioned at an area where a substrate is not positioned, the first negative pressure control valve is closed so that the chemical liquid is discharged from the venturi nozzle.

8. The substrate treatment apparatus of claim 1,
wherein when the chemical liquid is discharged to a substrate, in a state where the venturi nozzle is positioned at an area where the substrate is positioned, the first negative pressure control valve is closed so that the chemical liquid is discharged from the venturi nozzle.

9. The substrate treatment apparatus of claim 4, further comprising:
a controller configured to control operations of the discharge valve, the first negative pressure control valve, and the second negative pressure control valve.

10. The substrate treatment apparatus of claim 9,
wherein when an initial operation of the substrate treatment apparatus is started, the controller opens the first negative pressure control valve and closes the discharge valve to transfer the chemical liquid stored in the storage tank to the first negative pressure control valve.

11. The substrate treatment apparatus of claim 9,
wherein when foreign matter included in the chemical liquid is removed, the controller closes the first negative pressure control valve and opens the discharge valve to discharge the chemical liquid stored in the storage tank to an area where a substrate is not positioned for a reference time.

12. The substrate treatment apparatus of claim 11,
wherein the reference time is within a range from 8 seconds to 12 seconds.

13. The substrate treatment apparatus of claim 9,
wherein when a process of discharging the chemical liquid to a substrate is temporarily discontinued, the controller opens the first negative pressure control valve and opens the discharge valve, so that negative pressure is generated in the venturi nozzle.

14. The substrate treatment apparatus of claim 9,
wherein when the chemical liquid is discharged to a substrate, the controller closes the first negative pressure control valve and opens the discharge valve, so that the chemical liquid stored in the storage tank is discharged to the substrate.

15. The substrate treatment apparatus of claim 9,
wherein when a process of discharging the chemical liquid to a substrate is temporarily discontinued, the controller closes the first negative pressure control valve, opens the second negative pressure control valve, and opens the discharge valve, so that negative pressure is generated in the venturi nozzle.

16. A substrate treatment apparatus comprising:
a storage tank configured to store a chemical liquid;
a tube connected to a storage tank;
an outlet discharging the chemical liquid and connected to the tube;
a venturi nozzle including a body section installed in the tube and a chemical liquid discharge part configured to discharge the chemical liquid to a substrate;
a first negative pressure control valve installed between the venturi nozzle and the outlet in the tube; and
a controller configured to cause the first negative pressure control valve to open so that negative pressure is generated in the body section of the venturi nozzle to limit discharge of the chemical liquid from the chemical liquid discharge part to the substrate.

17. The substrate treatment apparatus of claim 16,
wherein the storage tank and the outlet are connected by a circulation tube so that the chemical liquid discharged from the outlet is introduced into the storage tank and circulated.

18. The substrate treatment apparatus of claim 16, further comprising:
a bubble removing member installed in the tube and configured to remove bubbles generated in the chemical liquid.

19. The substrate treatment apparatus of claim 16, further comprising:
a discharge valve coupled to the chemical liquid discharge part of the venturi nozzle and configured to control the discharge of the chemical liquid from the venturi nozzle.

20. A substrate treatment apparatus comprising:
a storage tank configured to store a chemical liquid;
a tube including a first end and a second end, the first end of the tube connected to the storage tank;
an outlet discharging the chemical liquid and connected to the second end of the tube;
a venturi nozzle including a body section installed in the tube and a chemical liquid discharge part configured to discharge the chemical liquid from the body section to a substrate;
a first negative pressure control valve installed between the venturi nozzle and the outlet in the tube;
a branch tube connected a portion, between the first end and the second end, of the tube;
a second negative pressure control valve connected to the branch tube; and
a controller configured to cause:
the first negative pressure control valve to open so that negative pressure is generated in the body section of the venturi nozzle to limit discharge of the chemical liquid from the chemical liquid discharge part to the substrate; and
the second negative pressure control valve to allow the negative pressure to be selectively generated in the body section of the venturi nozzle.
